(19) United States
(12) Patent Application Publication
(10) Pub. No.: US 2006/0105574 A1
(43) Pub. Date: May 18, 2006

(54) Process for defining integrated circuits in semiconductor electronic devices

(75) Inventors: Samantha Regini, Pavia (IT); Simone Alba, Milano (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.I., Agrate Brianza (IT)

(21) Appl. No.: 11/280,186

(22) Filed: Nov. 16, 2005

(30) Foreign Application Priority Data
Nov. 17, 2004 (IT) MI2004A002206

(51) Int. Cl. H01L 21/461; C23F 1/00; H01L 21/302

(52) U.S. Cl. 438/706; 438/710; 216/67

(57) ABSTRACT

A process for the definition of integrated circuits on a wafer having at least one silicon semiconductor layer includes masking the wafer with a photoresist layer. The process includes a development step of the photoresist with definition of a lithographic pattern, a hardening step of the photoresist with a plasma of inert gas, and a dry etching step with a plasma of reactive gas for transferring the lithographic pattern on the wafer. The dry etching step includes at least an initial step, or breakthrough, with a plasma of a chlorinated gas and of an inert gas for removal of a silicon native oxide grown on the wafer.

### FIELD OF THE INVENTION

The present invention relates in general to the manufacture of semiconductor electronic devices.

More particularly, the present invention relates to a process for defining integrated circuits, such as memory cells, for example, on a wafer having at least one silicon semiconductor layer masked with a film of photosensitive material, also called a photoresist layer. The process includes developing the photoresist layer with a lithographic pattern, hardening the photoresist through etching with a plasma of inert gas, and dry etching with a plasma of reactive gas for the transfer of the lithographic pattern onto the wafer.

### BACKGROUND OF THE INVENTION

The manufacture of semiconductor electronic devices includes subjecting silicon wafers to a series of chemical-physical treatments. This allows integrated circuits to be defined on the surface, such as a memory electronic device with non-volatile memory cells of the flash type, for example.

In particular, to transfer sub-micrometric geometries defined at the photoresist layer to layers of semiconductor silicon and to layers of a dielectric or metallic material, a process technique widely used and known is dry etching with a plasma of reactive gas (gas ionized at low pressure).

This technique is an anisotropic process, which allows the material to be exclusively removed in a direction perpendicular with respect to the underlying substrate. In particular, dry etching with a plasma includes a group of methods in which the solid surface of the wafer is etched by a physical etching with a plasma of gas (i.e., ionic bombing), or by chemical etching with a plasma of gas based upon a chemical reaction with a species present on the wafer surface. Alternatively, a combined chemical-physical etching can be used.

A process for defining a flash memory cell generally includes an integrated etching with a plasma, of two polysilicon layers separated by a thin film of dielectric material, such as ONO (i.e., a triple layer of oxide-nitride-silicon oxide).

After the deposition of the three layers on an underlying substrate, the wafer thus obtained is covered with a film of photosensitive material. The image of the lithographic pattern is defined in the photoresist by exposing it to UV radiation through a mask. The successive development allows removal of the photoresist portions irradiated, and thus defines the required pattern.

The definition of smaller and smaller geometries requires forming the photoresist on a layer of another organic material, known as BARC (bottom anti-reflective coating). BARC prevents the photoresist from being exposed to the radiation reflected by the underlying layers, thus jeopardizing the quality of the lithographic definition. The BARC is a non-photosensitive material and is added to the layers to be subsequently etched.

Once the lithographic pattern is defined, it is transferred into the BARC and into the polysilicon and ONO layers by a process, selective with respect to the photoresist, of dry etching with a plasma. The removal of the photoresist mask thus allows the defined structures to be disclosed.

Advanced technology for electronic devices requires, at present, a minimum lithographic spacing of 0.09 μm. This definition can be exclusively obtained by using resists that are photosensitive to the deep UV (Deep UV), for example, such as the photoresists at 193 nm, i.e., photoresists exposed to waves having a length equal to 193 nm.

The introduction of the deep UV lithography, such as 193 nm, for example, implies the use of thin photoresists having little resistance to etchings with plasma. This makes it difficult to develop traditional etchings with a plasma, such as those with a photoresist at 248 nm for the definition of flash memory cells.

In other words, the introduction in lithography of deep UV has a strong impact on the plasma etching processes. This is so since the definition of smaller and smaller geometries needs the use of photoresists with thinner thicknesses for improving the focus depth during the lithographic exposure.

This behavior variation is to be correlated to a change in the chemical composition of the material. In particular, the last typology of deep UV resists also shows characteristics of lower resistance to dry etchings with a plasma, thus a lower selectivity with respect to those of the previous technology at 248 nm.

The poor selectivity with respect to the photoresist has the consequence that it can be consumed before the etching of the underlying layer is completed. If the etching is drawn out, the upper part of the layer to be defined, which is not protected by the photoresist anymore, will undergo an unacceptable deterioration in the profile shape.

In fact, it has been found that an etching of the cell with photoresist at 193 nm using a process developed for the previous technologies with lithography at 248 nm results in irreparable consequences on the wafer.

FIG. 1 shows a section SEM (scanning electronic microscope) of a memory cell after subsequently being etched with a photoresist at 193 nm by using a process developed for the previous technologies with lithography at 248 nm. The photoresist seems completely consumed before the end of the etching, resulting in a loss of definition of the polysilicon layer (poly2).

In a view of this type, the demand for process technologies that are able to increase the selectivity of the dry etchings with a plasma with respect to the resists—exposed by wavelengths lower than 248 nm, such as resists at 193 nm, for example, are becoming more and more pressing.

There is a need for implementing a method that increases the resistance of the photoresist at 193 nm for dry etchings with a plasma in order to define integrated circuits, such as memory cells, for example. Some traditional methods are known which allow an increase in the resistance of the photoresist at 248 nm against the plasma etchings. The main examples are now reported below.

A first method provides a photo-stabilization of the resist. In particular, after the development of the resist, the wafer is exposed to UV radiation at high intensity and at high temperature (up to 200° C.). The disclosed method, which provides the use of special tools, causes cross-linking of the photoresist polymeric chains, thus increasing the resistance [The Platform for Excellence for Photoresist Processing, GEMINI].

However, this process technology cannot be introduced through lithography at 193 nm since the photoresists do not show an increase in the resistance to the etchings with plasma after UV treatment. Resist reflow phenomena have also been observed when the wafer is subjected to temperatures higher than 150° C. [M. Mariani, Investigation of UV curing feasibility on 193 nm photoresist, STMicroelectronics Technical Report, August 2002].

A second method widely used in polysilicon etching processes, which shows a poor selectivity towards the photoresist, is the use of a silicon oxide hard mask. The method includes depositing an additional layer above the polysilicon layer. The photoresist of the lithographic mask serves to define the oxide layer. This in turn will be used as a mask during the polysilicon etching.

In the case of the memory cell, this method creates some problems at the process integration level in the successive definition of the nitride spacers. Moreover, the removal of the hard mask immediately after the etching of the cell can damage the interpolysilicon dielectric layer, as well as the thin tunnel oxide layer that insulates the active area in the device matrix areas.

Recently, methods have been proposed which have been efficient on resist at 193 nm. Among these is and electronic bombing. This method allows stabilization of the photoresist through irradiation with an electronic beam. In this case, the resist's greatest resistance to the etching is obtained by making a cross-linking of the polymeric chains [M. Ross et al., Characterization of Electron Beam Stabilization of Deep-UV Resist, Proceedings of the Microlithography Seminar INTERFACE, 1997], i.e., through a reduction in some of the free volume due to the loss of carbonyl substituting groups of the resin [M. Padmanaban et al., E-beam Curing Effects on the Etch and CS SEM Stability of 193 nm Resists, Advances in Resist Technology and Processing XIX, 4690-70, Clariant Corporation].

This latter technology has some drawbacks. In particular, the problems relative to the electronic bombing are linked to the strong dimensional loss of the photoresist at 193 nm at the end of the treatment. In fact, it causes a shrinkage of about 25% of the polymeric material. This method also needs dedicated equipment, with a subsequent increase in the global number of process steps [M. Padmanaban et al., E-beam Curing Effects on the Etch and CS SEM Stability of 193 nm Resists, Clariant Corporation].

The most promising methodology for increasing the selectivity towards the photoresist 193 nm during the etching of the memory cell seemed to be the treatment of the resist with an argon plasma.

The method is performed in the plasma dry etching apparatus for a maximum duration of 20 seconds. After development of the photoresist, the wafer is subjected to a non-reactive plasma of an inert gas such as argon. As in the previous case, for increasing the resistance of the photoresist, the synergetic effect of the cross-linking of polymeric chains and of the sputtering of the substrate to be etched on the sidewalls of the resist is exploited.

The technique of inert gas plasma etching is described in U.S. Pat. No. 6,495,455 which is assigned to the current assignee of the present invention and is incorporated herein by reference in its entirety. This patent is directed to a method for enhancing selectivity between a film of a light sensitive material, and a layer to be etched in the electronic semiconductor device fabrication processes.

This method is used when the wafer is made of metallic layers, such as aluminium. This requires chemistry based on chloride for the successive dry etching with a plasma. In particular, this method cannot be used in case the wafer is made with polychrystalline silicon layers.

In the definition of polycrystalline layers, it is necessary to provide the etching of the wafer to obtain also the initial removal of a silicon native oxide layer, i.e., grown on the poly through reaction with the atmospheric oxygen. This removal is generally carried out with a short etching (breakthrough) in CF₄ (or C₂F₆). This is a process with a selectivity of 1:1 between silicon and silicon oxide. The process includes a homogeneous etching front without leaving residues.

It has been verified that the treatment of the photoresist at 193 nm with an argon plasma is not efficient when it is associated with the successive etching of polysilicon layers with a traditional breakthrough in CF₄.

By analyzing a section SEM of a memory cell made by this method, as shown in FIG. 2, it is possible to verify that the thickness of the residual resist is very low (500 Å), and is normally arranged in the center of the gate. On the sides, the photoresist is very thin and may even be non-existent. The profile of the upper part of the cell thus shows itself as non-correctly defined.

### SUMMARY OF THE INVENTION

In view of the foregoing background, an object of the present invention is to provide a process for defining integrated circuits on wafers during a dry plasma etching that allows for an increase in the selectivity between a deep UV photoresist film, such as at 193 nm, for example, and the underlying silicon layers forming the wafer.

This and other objects, features and advantages in accordance with the present invention are provided by a process in which the dry etching step with a plasma of reactive gas comprises at least an initial etching, or breakthrough, with a plasma of a chlorinated gas and of an inert gas, wherein silicon native oxide grown on the wafer is removed.

### BRIEF DESCRIPTION OF THE DRAWINGS

Further characteristics and advantages of the process according to the invention will be apparent from the following description of an embodiment thereof given by way of illustrations and of non-limiting examples with reference to the annexed drawings.

FIG. 1 shows a section SEM of a memory cell obtained according to a prior art process.

FIG. 2 shows a section SEM of a memory cell obtained according to another prior art process.

FIGS. 3A-3G are cross-sectional views of a wafer illustrating a sequence of the process steps according to the present invention.

FIG. 4 shows a section SEM of a memory cell obtained according to the process of the present invention.

FIG. 5 shows a section SEM of a memory cell obtained according to the process of the present invention, with the photoresist having been removed.

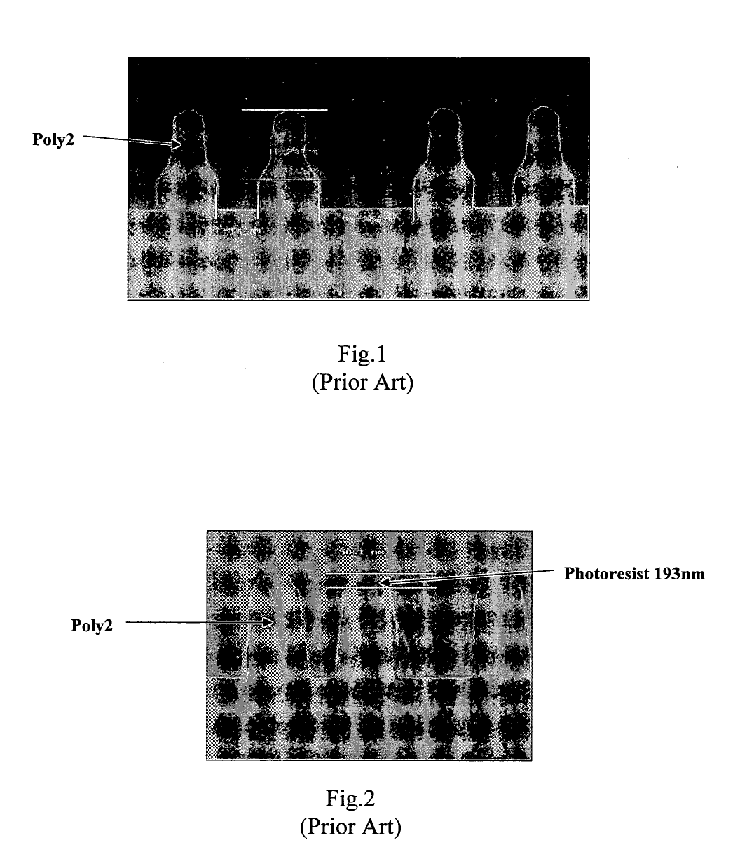

### DETAILED DESCRIPTION OF THE PREFERRED EMBODIMENTS

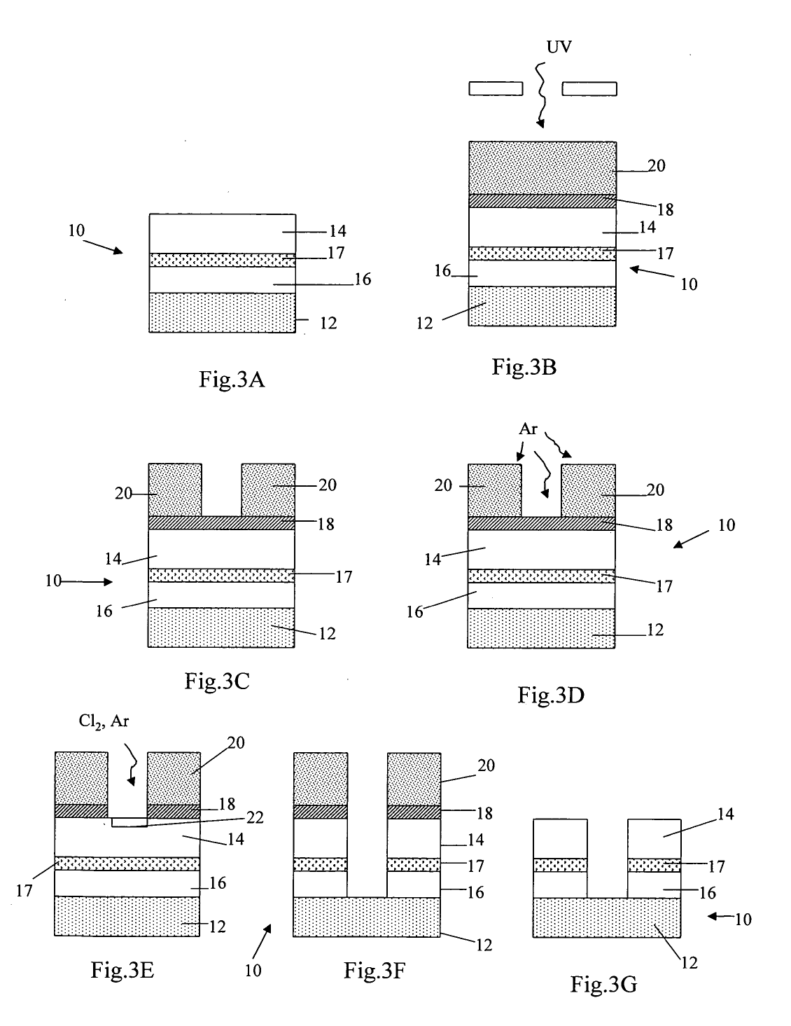

With reference to the figures, and in particular to FIGS. 3A-3G, reference 10 globally and schematically indicates a wafer of semiconductor material. The wafer 10 comprises at least one silicon semiconductor layer subjected to the sequence of process steps according to the present invention.

The process steps and the structures described below do not form a complete process flow for the manufacturing of integrated circuits. In fact, the present invention can be put into practice together with the manufacturing techniques of the integrated circuits currently used in the field. The process steps that are commonly used are described below since they are necessary for understanding the invention.

The figures show cross sections of the semiconductor wafer 10 integrated on a substrate 12 during its manufacturing. The figures are not drawn to scale, but instead, are drawn so as to show the important characteristics of the invention.

In the specific case, which is non-limiting within the scope of the present invention, the wafer 10 (FIG. 3A) comprises two polysilicon layers 14 and 16 and a layer of dielectric material 17 such as, for example, a triple layer of oxide-nitride-silicon oxide (ONO). According to a further embodiment, in addition to polysilicon, metallic layers can be used, such as tungsten silicide layers (WSi₂), for example.

Preferably, the wafer 10 comprises a layer of anti-reflective organic material 18 known as BARC, i.e., a bottom anti-reflective coating). As mentioned above, this layer 18 has the task of preventing the photoresist from being exposed to the radiation reflected by the underlying layers, thus jeopardizing the quality of the lithographic definition.

With reference to FIGS. 3A-3G, the process comprises the following steps schematically indicated. FIG. 3B illustrates a masking step of the wafer 10 by a photoresist layer 20. FIGS. 3B and 3C illustrate a development step of the photoresist 20 for defining a lithographic pattern thereon. FIG. 3D illustrates a hardening step of the photoresist 20 by an etching with a plasma of inert gas, preferably argon. FIGS. 3E and 3F illustrate a dry etching step with a plasma of reactive gas on the silicon wafer for transferring the lithographic pattern thereon.

The first three steps of masking, developing and hardening of the photoresist with a plasma of inert gas are carried out according to what has been described in the above referenced U.S. Pat. No. 6,945,455. The hardening of the photoresist, induced by the etching of argon, is obtained through cross-linking of the polymeric chains caused by the ionic bombing. To this effect, in the specific case, the sputtering of the BARC is added on the sidewalls of the photoresist, thus forming a protective layer thereon.

Preferably, the etching step with argon plasma is drawn out for an interval of at least about 50 seconds. This allows a complete removal of the BARC layer having, for example, a thickness of about 800 Å.

According to the invention, the above dry etching step with a plasma of reactive gas on the wafer 10 comprises at least an initial etching or breakthrough with plasma of a chlorinated gas and of an inert gas, preferably argon. This etching allows selective removal of a silicon native oxide 22 grown on the silicon wafer (FIG. 3E). The chlorinated gas is molecular chlorine, Cl₂, for example.

According to a further embodiment, the chlorinated gas is boron tri-chloride, BCL₃. In other words, the dry etching step with plasma provides, according to the invention, a chemistry based on chlorine and a inert gas such as argon, for example.

Preferably, the etching with a plasma of chlorinated gas and the etching with a plasma of inert gas is carried out simultaneously and in a ratio of about 1:1 for the flow of the two gases.

Preferably, the ions of the gases are accelerated until they reach an energy equal to 85 eV. To carry out the etching with a plasma of chlorinated gas and of an inert gas, ionized gases are used having common ionization parameters.

Preferably, the plasmas based on chlorine and on an inert gas, have an ionization equal to about 10⁻⁴ to 10⁻⁶, which is intended as a ratio between charged species and neutral species. This is commonly used in dry plasma etching processes with lithographic masks.

An etching apparatus, such as a polyetcher LAM Alliance TCP 9400 DFM, can be used. The operating conditions used are preferably a pressure of 10 mTorr, a power on the upper electrode of 450 W, a voltage on the lower electrode of −85V, and respective flows of chlorinated gas and inert gas at 70 sccm and 100 sccm. Preferably, the same tools are used as those used for the hardening and etching with the plasma of inert gases.

According to the invention, the traditional step of breakthrough in CF₄ is substituted with a step in chlorinated gas/inert gas. In the specific case where the etching with a plasma of chlorinated gas/inert gas occurs by argon and molecular chlorine, the etching is carried out with a not so high etch-rate on oxide of about 500 Å/min. Advantageously, this etching is characterized by a very high etching rate on the photoresist 20 and polysilicon layers 14, 16, which is higher than 2500 Å/min.

The etching is preferably carried out in very short times, on the order of seconds, and preferably 10-12 seconds. The etching with a plasma of argon and molecular chlorine carried out under the above conditions allows removal of the residues of BARC, and etching of the thin silicon native oxide layer to a depth that enters into the polysilicon layers 14, 16.

Preferably, the etching with a plasma of argon and molecular chlorine is carried out to penetrate for about 200 to 300 Å into the polysilicon 14 with a very uniform etching front. The etching with a plasma of argon and molecular chlorine is then used also for the etching of a single polysilicon layer.

The dry etching step is completed by further etching steps with a plasma of the standard type, for example, in CL₂/HBr which allows the definition of the structure profiles in the wafer 10 (FIG. 3F) to be controlled.

The process preferably comprises a final step of dry etching with a reactive plasma with use of small amounts of gases containing fluoride to obtain a complete definition of the layers forming the memory cell.

The percentage of flow of fluorinated gases, such as CF₄, for example, with respect to the total flow present in the single final steps, must not overcome 20% so that the thickness of residual resist 20 falls within the specific requirements.

The fluorinated gases are mainly used for the etching of the dielectric layer. The remaining 80% of the plasma flow used comprises chlorine, and an inert and diluting gas such as helium, He.

The operating conditions of this final step are at a pressure of 8 mTorr, a power on the upper electrode at 350 W, a voltage on the lower electrode at −135V, a flow of He at 250 sccm, a flow of Cl₂ at 15 sccm, and a flow of CF₄ at 40 sccm.

In another embodiment, the fluorinated gas is used under the same operating conditions just described, during the etching of the second poly layer 16. In this case, the remainder 80% of the plasma flow used comprises standard gases such as chlorine (Cl₂), hydrogen bromide (HBr) or oxygen (O₂). Once the definition of the geometries is completed, the portions of photoresist 20 are removed in a known way, so as to detect the required lithographic pattern (FIG. 3G).

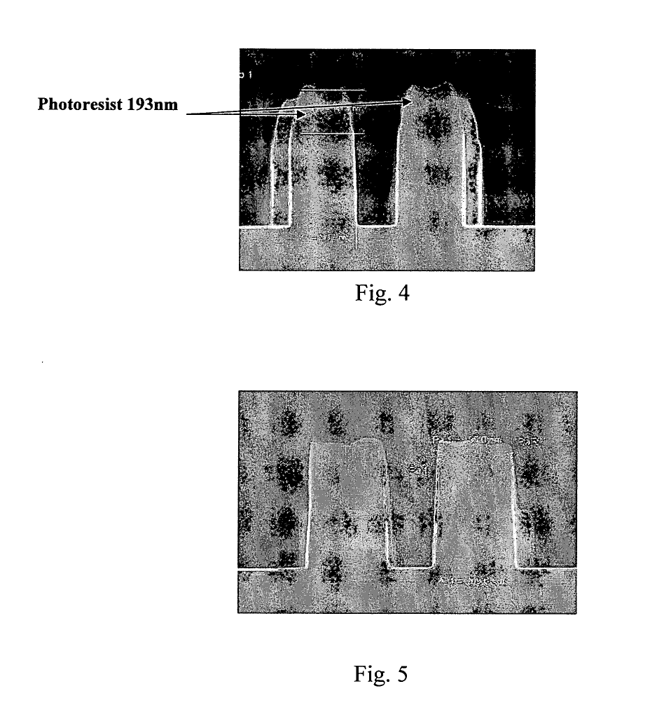

With reference to FIGS. 4 and 5, the sections SEM of a memory cell are shown, formed by using the proposed method after exposure with a photoresist of 193 nm from 3300 Å, and respectively after the removal of the photoresist 20. The profile of the defined structures do not appear to be deteriorated, and the photoresist thickness at the end of the etching is about 1500 Å.

FIGS. 4 and 5 are to be compared with FIG. 2. In particular, the cells shown in FIG. 2 and in FIGS. 4-5 have undergone, under the same conditions, a masking step of the wafer 10 using a photoresist 20. A development step of the photoresist 20 is performed for the definition of a lithographic pattern thereon, and a hardening step of the photoresist 20 is performed by an etching with an argon plasma.

The difference between the cells resides in the use of a traditional breakthrough in CF₄ in the case of FIG. 2, and in the use of a breakthrough in Cl₂/Ar according to the invention in the case of FIGS. 4 and 5.

The main advantage of the present invention is the use of a chemistry based on chlorine/inert gases for the initial removal of a silicon native oxide layer. This allows the resist hardening obtained in the previous step not to be altered, and to advantageously allow an etching with a plasma on the polysilicon and ONO layers.

In other words, the process according to the invention offers the advantage of maintaining the treatment with argon efficient for hardening the photoresist (without losing the selectivity to a dry etching with a plasma of reactive gas), and at the same time removing the native oxide layer from the wafer (without affecting or ruining the hardening obtained).

It has been verified that due to the etching in chlorinated gas and inert gas, preferably Ar, the treated photoresist maintains its properties of greater resistance to the dry etching with plasma for longer periods during the whole definition process of the memory cell.

Another advantage is that the same etching with a plasma of Cl₂/Ar can be used for etching single polysilicon or metallic layers such as tungsten silicide. Moreover, in the specific case, the combination of the breakthrough step with the hardening treatment in argon of the photoresist, also allows the use of small amounts of gases containing fluoride in the above final step during the definition process of the layers forming the memory cell.

As mentioned above the percentage of flow of fluorinated gases with respect to the total flow present in the single steps should not be more than 20% so that the thickness of residual resist falls within the specific requirements.

Moreover, the process according to the invention can be developed in the specific case wherein the definition of the lithographic pattern occurs above a layer of anti-reflective organic material (BARC). The process according to the present invention also has the advantage of being very versatile, and can be applied to any type of structure that is to be defined on the polysilicon (floating gate, circuitry).

The entire methodology also shows the advantage of being applied using the same equipment, wherein the hardening etching in a plasma of inert gas is carried out. Also, the whole execution of the process is very advantageous. Other operations and tools different from those of plasma etching wherein the entire process is carried out are not necessary.

1-25. (canceled)

26. A process for defining integrated circuits on a wafer comprising:
forming at least one silicon semiconductor layer on a substrate having a silicon native oxide layer thereon;
masking the at least one silicon semiconductor layer with a photoresist layer;
defining a lithographic pattern in the photoresist layer;
hardening the photoresist layer with a plasma of an inert gas; and
transferring the lithographic pattern onto the wafer using a dry etching with a plasma of a reactive gas, the transferring comprising an initial dry etching using a plasma of a chlorinated gas and the inert gas for removing at least a portion of the silicon native oxide layer.

27. A process according to claim 26, wherein the inert gas comprises argon gas.

28. A process according to claim 26, wherein the chlorinated gas comprises molecular chlorine.

29. A process according to claim 26, wherein the chlorinated gas comprises boron tri-chlorine.

30. A process according to claim 26, wherein the initial dry etching using the plasma of the chlorinated gas and the inert gas is carried out simultaneously.

31. A process according to claim 26, wherein the initial dry etching using the plasma of the chlorinated gas and the inert gas is carried out with a flow ratio of about 1:1 for the two gases.

32. A process according to claim 26, wherein the initial dry etching using the plasma of the chlorinated gas and the inert gas is carried out by accelerating ions up to an energy equal to about 85 eV.

33. A process according to claim 26, wherein the initial dry etching using the plasma of the chlorinated gas and the inert gas is carried out at a pressure of about 10 mTorr.

34. A process according to claim 26, wherein the initial dry etching using the plasma of the chlorinated gas and the inert gas is carried out with the inert gas having a flow rate equal to about 100 sccm.

35. A process according to claim 26, wherein the initial dry etching using the plasma of the chlorinated gas and the inert gas is carried out with the chlorinated gas having a flow rate equal to about 70 sccm.

36. A process according to claim 26, wherein the chlorinated gas comprises a chlorine gas and the inert gas comprises an argon gas; and wherein the initial step using the plasma of the chlorine gas and the argon gas is carried out to obtain an etch-rate on the silicon native oxide layer equal to about 500 Å/min.

37. A process according to claim 26, wherein the chlorinated gas comprises a chlorine gas and the inert gas comprises an argon gas; and wherein the initial step using the plasma of the chlorine gas and the argon gas is carried out to obtain an etch-rate on the photoresist layer and the at least one silicon semiconductor layer greater than 2500 Å/min.

38. A process according to claim 26, wherein the chlorinated gas comprises a chlorine gas and the inert gas comprises an argon gas; and wherein the initial step using the plasma of the chlorine gas and the argon gas is carried out within a range of about 10 to 12 seconds.

39. A process according to claim 26, wherein the chlorinated gas comprises a chlorine gas and the inert gas comprises an argon gas; and wherein the initial step using the plasma of the chlorine gas and the argon gas is carried out for a penetration of about 200-300 Å in the silicon native oxide layer and the at least one silicon semiconductor layer.

40. A process according to claim 26, wherein the hardening is carried out for an interval of at least about 50 seconds.

41. A process according to claim 26, wherein the wafer further comprises a bottom anti-reflective coating (BARC) layer between the photoresist layer and the at least one silicon semiconductor layer.

42. A process according to claim 41, wherein the BARC layer has a thickness of about 800 Å.

43. A process according to claim 26, wherein the transferring further comprises a final dry etching using a plasma of gas containing fluorine.

44. A process according to claim 43, wherein a percentage of flow of the fluorine gas is no greater than 20% with respect to a total plasma flow during the final dry etching.

45. A process according to claim 44, wherein a remaining flow of the total plasma flow during the final dry etching comprises a chlorine and helium flow.

46. A process according to claim 44, wherein a remaining flow of the total plasma flow during the final dry etching comprises a plasma of at least one of chlorine, hydrogen bromide and oxygen.

47. A process according to claim 26, wherein the at least one silicon semiconductor layer comprises two polysilicon layers, and the wafer further comprises a dielectric layer between the two polysilicon layers.

48. A process according to claim 26, wherein the wafer further comprises a metallic layer adjacent the substrate.

49. A process according to claim 26, wherein the initial dry etching and the hardening are carried out using a same apparatus.

50. A process for defining integrated circuits on a wafer comprising:
forming at least one semiconductor layer on a semiconductor substrate having a native oxide layer thereon;
masking the at least one semiconductor layer with a photoresist layer;
defining a lithographic pattern in the photoresist layer;
hardening the photoresist layer; and
transferring the lithographic pattern onto the wafer, the transferring comprising an initial dry etching using a plasma of a chlorinated gas and an inert gas for removing at least a portion of the native oxide layer.

51. A process according to claim 50, wherein the inert gas comprises argon gas.

52. A process according to claim 50, wherein the chlorinated gas comprises at least one of chlorine and boron tri-chlorine.

53. A process according to claim 50, wherein the initial dry etching using the plasma of the chlorinated gas and the inert gas is carried out simultaneously.

54. A process according to claim 50, wherein the initial dry etching using the plasma of the chlorinated gas and the inert gas is carried out with a flow ratio of about 1:1 for the two gases.

55. A process according to claim 50, wherein the initial dry etching using the plasma of the chlorinated gas and the inert gas is carried out by accelerating ions up to an energy equal to about 85 eV, and at a pressure of about 10 mTorr.

56. A process according to claim 50, wherein the initial dry etching using the plasma of the chlorinated gas and the inert gas is carried out with the inert gas having a flow rate equal to about 100 sccm, and the chlorinated gas having a flow rate equal to about 70 sccm.

57. A process according to claim 50, wherein the chlorinated gas comprises a chlorine gas and the inert gas comprises an argon gas; and wherein the initial step using the plasma of the chlorine gas and the argon gas is carried out to obtain an etch-rate on the native oxide layer equal to about 500 Å/min.

58. A process according to claim 50, wherein the chlorinated gas comprises a chlorine gas and the inert gas comprises an argon gas; and wherein the initial step using the plasma of the chlorine gas and the argon gas is carried out to obtain an etch-rate on the at least one semiconductor layer and the photoresist layer greater than 2500 Å/min.

59. A process according to claim 50, wherein the chlorinated gas comprises a chlorine gas and the inert gas comprises an argon gas; and wherein the initial step using the plasma of the chlorine gas and the argon gas is carried out for a penetration of about 200-300 Å in the native oxide layer and the at least one semiconductor layer.

60. A process according to claim 50, wherein the wafer further comprises a bottom anti-reflective coating (BARC) layer between the photoresist layer and the at least one semiconductor layer.
